(19) United States
(12) Patent Application Publication
(10) Pub. No.: US 2009/0277503 A1
(43) Pub. Date: Nov. 12, 2009

(54) Solar Cell with Current Blocking Layer

(75) Inventor: Michael J. Ludowise, San Jose, CA (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/401,546

(22) Filed: Mar. 10, 2009

Related U.S. Application Data
(60) Provisional application No. 61/052,196, filed on May 10, 2008.

(51) Int. Cl. H01L 31/00; B05D 7/00

(52) U.S. Cl. 136/256; 427/74

(57) ABSTRACT

A solar cell includes an active layer, a blocking layer and a contact layer. The blocking layer is disposed between a portion of the top surface of the active layer and the bottom surface of the contact layer. The blocking layer serves to reduce current flow between the contact layer and the portion of the active layer covered by the blocking layer. Current flow to the contact layer may occur via gridlines electrically connecting the active layer to the contact layer.

### RELATED APPLICATIONS

This application claims priority to U.S. Provisional Patent Application Ser. No. 61/052,196 filed on May 10, 2008, entitled “Solar Cell with Current Blocking Layer,” which is hereby incorporated by reference as if set forth in full in this application for all purposes.

### BACKGROUND

The present invention relates generally to the field of solar cells. In particular, the present invention relates to electrical protection systems for solar cells in concentrating photovoltaic systems. A concentrating solar radiation collector may convert received photons (i.e., sunlight) into a concentrated beam of photons and direct the concentrated beam onto a small photovoltaic solar cell such as a multi-junction solar cell. A photovoltaic (or, “solar”) cell generates charge carriers (i.e., holes and electrons) in an active layer in response to received photons. Many types of solar cells are known, which may differ from one another in terms of constituent materials, structure and/or fabrication methods. A solar cell may be selected for a particular application based on its efficiency, electrical characteristics, physical characteristics and/or cost. The semiconductor material of the active layer (e.g., silicon) of a solar cell contributes significantly to total solar cell cost. Accordingly, many approaches have been proposed to increase the working lifetime of a solar cell for a given amount of active semiconductor material. A concentrating solar radiation collector, for example, may receive solar radiation (i.e., sunlight) over a first surface area and direct the received sunlight to a portion of an active layer of a solar cell. The active layer of the solar cell is several times smaller than the first surface area of the collector, yet receives substantially all of the photons received by first surface area. The solar cell may thereby provide an electrical output equivalent to a solar cell having the size of the first surface area.

Multi-junction solar cells such as III-V cells may make better use of the solar spectrum than cells with a single p/n junction by having multiple active layers with different bandgaps. Each layer is made of a different material, and absorbs a different portion of the spectrum. The top layer has the largest bandgap so that only the most energetic photons are absorbed in this layer. Less energetic photons must pass through the top layer since they are not energetic enough to generate electron hole pairs (EHPs) in the material. Each layer going from the top to the bottom has a smaller bandgap than the previous. Therefore, each layer absorbs the photons that have energies greater than the bandgap of that layer and less than the bandgap of the higher layer. Electrical energy generated at the active layer flows to a metal contact layer which directs the electricity to a circuit for connection to an electrical network. Thus, multi-junction solar cells are well suited to convert the photons of the concentrated beam into useable electrical current but may also suffer from degradation due to high current flux.

The active layer of solar cells is generally fabricated using semiconductor processing technology and subject to periodic quality control testing. During high current Dark Current Voltage (DIV) testing, and also occasionally during on-sun operation, the solar cell may develop a hot spot on the contact layer, that may be caused by the presence a small void in the die-attach epoxy or any other imperfection in the solar cell. This hot spot creates a thermal run-away situation ending when the contact metal dissolves into the cell active layers and shorts out the cell, permanently damaging it. Additionally the cells may be subject to high electrical fluxes during their working lifetimes causing them to be susceptible to reverse bias breakdown in the field as well. It is desirable to safeguard solar cells from potential damage caused by high flux conditions.

### SUMMARY

The solar cell of this invention may reduce the likelihood of damage to an active photovoltaic layer from forward current flow by comprising a blocking layer between the contact layer and active layers of a solar cell. The solar cell comprises a photovoltaic active layer with an upper surface, and a top contact layer with a bottom surface. A blocking layer is disposed between the bottom surface of the contact layer and a portion of the upper surface of the active layer. Gridlines may be disposed on a portion of the top surface of the active layer and connected to the side surface of the contact layer to transmit current generated by the active layer to the contact layer. The blocking layer may be any dielectric material such as SiN, polyamide, SiO₂, or Si₃N₄. The area of the blocking layer need not be the same as the area of the contact layer. The solar cell may include additional layers such as an anti-reflective coating, passivation layer or light trapping material. The active layer may be a multi-junction solar cell such as a III-V triple junction solar cell.

The solar cell of this invention may be fabricated by standard methods of solar cell manufacture to form a protective blocking layer that may reduce cell damage from high current flux through a contact layer to an active layer. The solar cell of this invention may be made by any method known in the art for fabricating solar cells such as epitaxial or diffusion methods. The blocking layer may be applied to an active layer by any method known in the art such as masking and etching techniques. The solar cell provided by this invention may reduce current leakage and improve the lifetime efficiency of concentrated solar energy devices.

### DESCRIPTION OF THE DRAWINGS

FIG. 1 provides a schematic cross-sectional view of a prior art solar cell.

FIG. 2 provides a detailed schematic cross-sectional view of an embodiment of the present invention.

FIG. 3 provides a top schematic view of one embodiment of the present invention.

FIG. 4 depicts a flow chart of embodiments for the method of manufacture of the present invention.

### DETAILED DESCRIPTION

In the following description, reference is made to the accompanying drawings which form a part hereof and show, by way of illustration, several embodiments of the present invention. It is understood that other embodiments may be utilized and structural changes may be made without departing from the scope of the present invention.

The present invention provides an improved solar cell with a blocking layer between a contact layer and an active layer. The improved solar cell may provide protection from failure due to forward bias driven tests at high current or from failing during on-sun operation due to a current leakage and cell damage. Current leakage may occur in any solar cell, but is more likely in cells with imperfections. The active layers of a solar cell made by epitaxial or diffusion techniques may be subject to imperfections or inhomogeneities at the active layer surface as the result of the manufacturing process. These imperfections may lead to a current leakage at the junction of a contact layer and the shaded portion of the active layer when current generated at the exposed portion of the active layer flows back into the active layer via the contact layer. Heat generated by these ‘hot spots’ in the current flow may significantly reduce the useable lifetime of the solar cell.

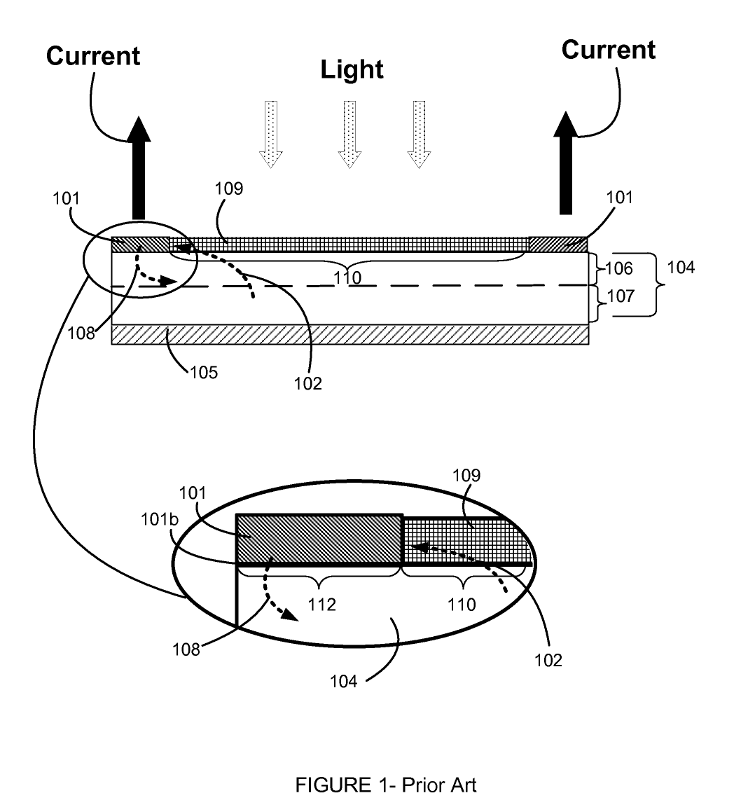

FIG. 1 shows a schematic diagram and insert diagram of a prior art arrangement of a solar cell to illustrate a failure mechanism of some solar cells from exposure to current leakage. The solar cell may include a photovoltaic active layer 104 disposed on a metal back contact layer 105. A top contact layer 101 receives current generated by the active layer 104. The top contact layer 101 may also be known as a bus bar. The active layer 104 generally includes at least one p/n junction between epitaxial layers n 106 and a p 107 to facilitate the generation of electricity from solar radiation. The active layer 104 may be made of a semiconductor material (i.e. doped silicon). Electrical current 102 may be generated at the active layer 104 when the exposed region 110 receives light. The electricity 102 may be conducted from the surface of the active layer 104 to the top metal contacts 101 via grid lines 109. This design is prone to failure at the point of contact between the bottom surface 101b of the top metal contact layer 101 and the shaded region 112 of active layer 104. This occurs when the current flow experiences a smaller built in potential at the shaded portion 112 of the active layer 104 and current 108 leaks back into the active layer 104 rather than flows out to an electrical network. As current 108 flows back into the active layer 104, the shaded portion 112 of the active layer 104 heats up, and consequently current leakage increases, leading ultimately to the failure of the solar cell. This failure mode may occur under working conditions if electrons generated by solar irradiation are directed towards the top contact layer 101 through the shaded region 112 of the active layer 104. Failure can also occur during forward bias driven tests as high current is directed through the top contacts and the active layer, for example during electrical stress testing. Excess leakage current may then be directed through the top contact 101 onto the active layer 104 causing a portion of the active layer 104 to heat and dissolve, permanently damaging the solar cell. These failure modes may be exacerbated by any imperfection in the active layer 104 such as inhomogeneities in the epitaxial layers 106 and 107, or die attach voids under the top contact layer 101 which may reduce the built in potential of the shaded portion 112 of the photovoltaic active layer.

The most damaging failure mode may occur during on-sun operation; when the shaded portion of the cell underneath the contact layer (101) can be toggled into dark conduction forward current because of either a manufacturing flaw in the epitaxial material or a small void in the die attach epoxy. In the former case, the cell bandgap may be somewhat smaller at the defect; in the second case the added thermal rise leads to a small amount of bandgap shrinkage. In both cases, additional current is funneled through the smaller bandgap region, causing it to heat more than the surrounding active layer. This may promote increased current underneath the top contact layer. Often the contact layer may then fuse with the active layer and penetrate the entire solar cell structure, shorting the cell permanently. This invention guards against failure mechanisms related to materials inhomogenieties or die attach voids under the top contact layer or any imperfection of the top contact layer or solar cell that may result in a high current flow under the top contact layer or other shaded area by introducing a blocking layer to impede electrical current between the active layer and the top contact layer.

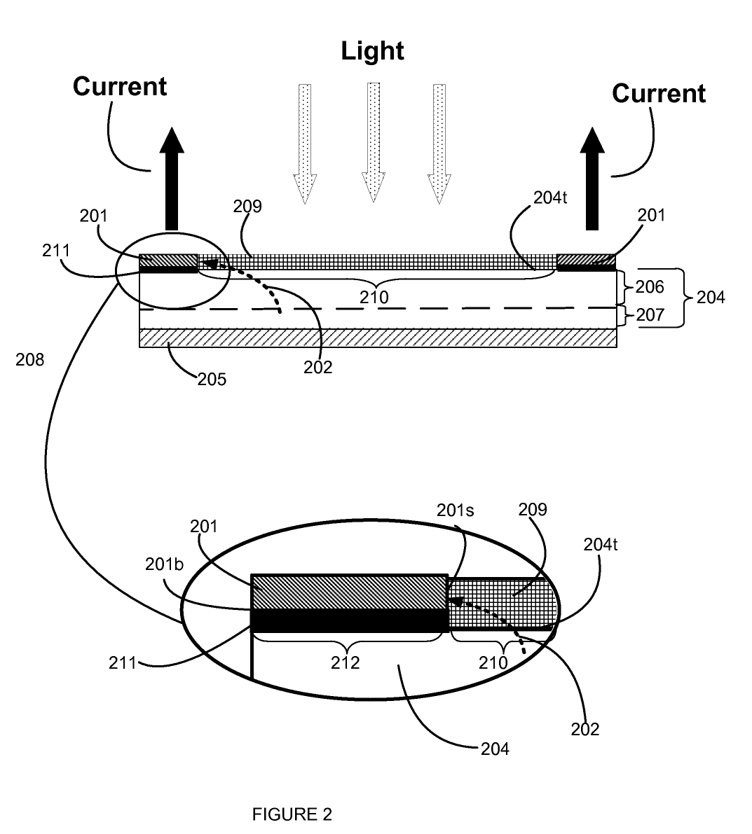

Referring now to FIG. 2, there is shown a schematic view of one embodiment of this invention including a detailed view of the blocking layer 211 (insert). The solar cell of this invention may have a back contact layer 205 disposed under a photovoltaic active layer 204. In the embodiment shown, the active layer 204 contains a single p/n junction separating epitaxial layers 206 and 207. In other embodiments of this invention, the active layer 204 may contain multiple p/n junctions, or the active layer may be a III-V multi-junction cell. The active layer 204 may include a top surface 204t for receiving light or additional layers. Light may reach the exposed portion 210 of the top surface 204t of active layer (see insert) and a current 202 may be generated by photons impinging into the active layer and generating an electron flow between the n and p regions. The solar cell may include gridlines 209 covering a portion of the top surface 204t of the active layer 204. In one embodiment, the gridlines 209 may be capable of transmitting an electrical current 202 from the active layer 204 to the side surface 201s of the top contact layer 201 for transmission to an electrical circuit. The gridlines 209 may be composed of any suitable metallic or highly conductive material such as silver or gold. The solar cell of this invention includes a blocking layer 211 disposed between the bottom surface 201b of the top contact layer 201 and a portion of the top surface 204t of the active layer 204. In one embodiment of this invention, the blocking layer 211 is located directly beneath the metal contact layer 201, covering the area of the active layer 204 that is shaded by the contact layer 201. The area of the active layer 204 that is covered by a blocking layer 211 and a contact layer 201 may be substantially the same. In an alternative embodiment the area of the blocking layer 211 may exceed that of the contact layer 201.

The blocking layer may be comprised of any material that impedes current flow. The blocking layer may include a dielectric material, for example polyamide, silicon nitride, silicon dioxide, oxidized aluminum bearing III-V, or any other material known in art to form a dielectric layer. In one embodiment the blocking material may include SiNₓ, polyamide, SiO₂, or Si_{y}Nₓ where x is any number from one to five and y is any number from 1 to 5. In one embodiment the blocking layer may be made of a semiconductor material with a high band gap (i.e. lightly doped A10.90Ga0.10As or In(Ga0.01 A10.9)P). The blocking layer may be, for example, between 50 angstroms and 1 micron thick. In one embodiment, the blocking layer may be less than 200 angstroms thick. The vertical current transport under the contact layer 201 may be interrupted by the blocking layer 211. In doing so, the current leakage cycle may fail to initiate. The blocking layer of this invention may be used under any shadowed areas of the photovoltaic active layer such as the contact layer or any other metallization area used to extract current or any other layer that may shade the active layer of the solar cell.

In still another embodiment of this invention a thin adhesion layer (not shown) may be disposed between the blocking layer 211 and the active layer 204 to facilitate adhesion of a blocking layer 211 to the active layer 204. The adhesion layer may include, for example, titanium, nickel, nickel chromium or any other material known in the art for promoting adhesion to a photovoltaic active layer. The adhesion layer may be either conductive or insulating.

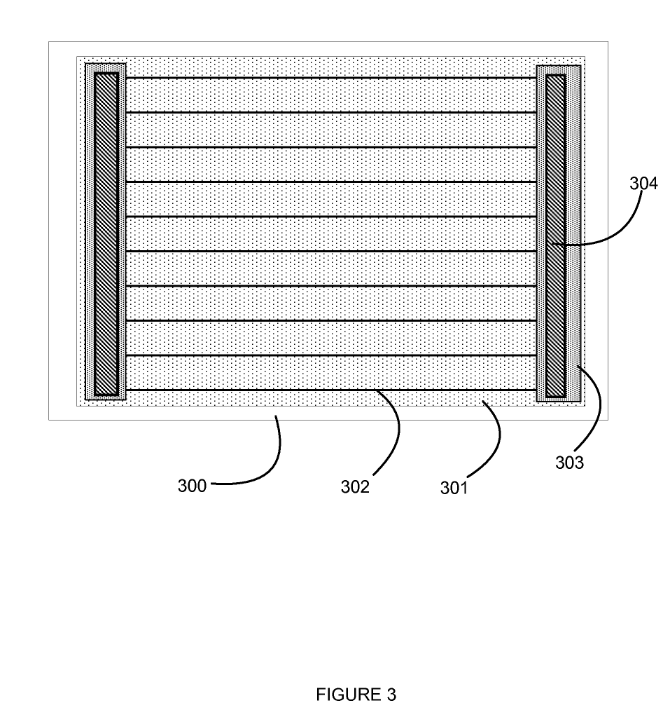

FIG. 3 provides a schematic top view of a further embodiment of this invention. The active layer 301 may be disposed on a back contact layer 300. The area of the back contact 300 and active layers 301 may be the same or different sizes. The blocking layer 303 may be disposed on one or more portions of the active layer 301. The top contact layer 304 may be disposed on one or more portions of the blocking layer 303. The area of the blocking layer 303 may exceed or be substantially the same as the area of the top contact layer 304. In one embodiment the top contact layer 304 and the blocking layer 303 may be one or two or more narrow strips at the edges of the top surface of the active layer. The arrangement of top contact layer 304 and the blocking layer 303 at the edges of the active layer 301 advantageously provides for a relatively large portion of the surface area of the active layer to be available for exposure to light. This arrangement beneficially protects the active layer 301 from damage due to forward current flow from the top contact layer 304 and provides a large exposed portion of a photovoltaic active layer. Current generated from the active layer 301 may be transferred to the top contact layer via a series of grid lines 302 that connect the surface of the active layer 301 to the side of the top contact layer 304. The presence of the blocking layer 303 may impede vertical current transport in the shaded portion of the active layer beneath the contact layer while the grid lines remain in contact with the active layer and a side of the contact layer to transmit the photocurrent efficiently.

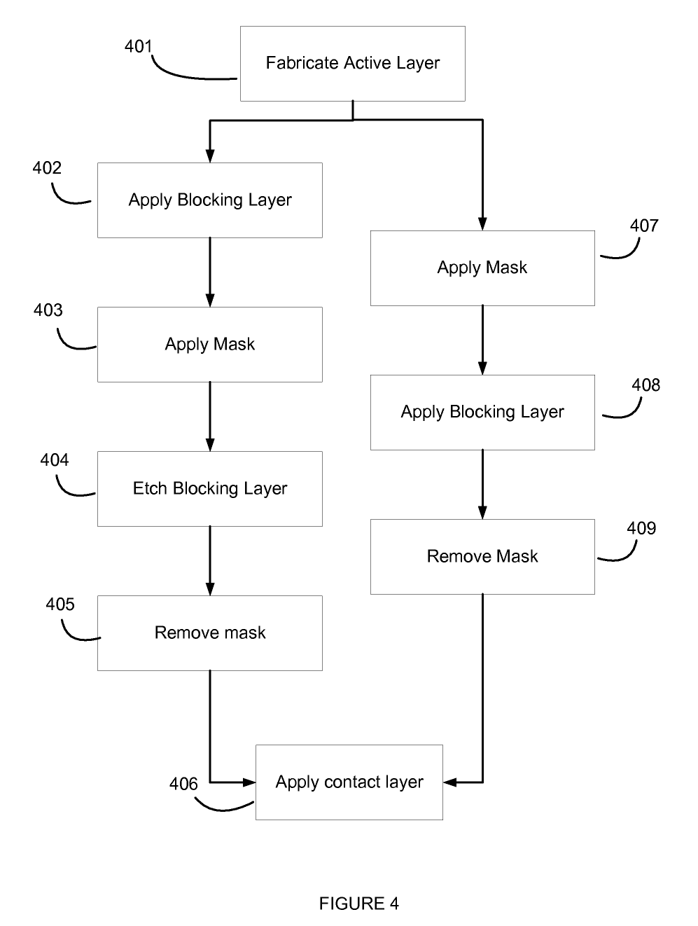

The solar cell of this invention may be made by any means including epitaxial growth, diffusion, thin film deposition or any other method known in the art for preparing solar cells. Embodiments of the method of this invention are shown in FIG. 4 whereby masking layers may be used to locate the blocking layer. This may be done during the solar cell fabrication process after the active layer is fabricated 401. In one embodiment a blocking layer is uniformly deposited across the active layer surface 402, subsequently a photo resist mask may be applied 403, exposing and developing the mask to reveal open areas in all places the blocking layer is not desired, and etching away the dielectric material in those regions 404, and finally removing the photoresist mask 405 before continuing on to apply the contact layer 406. Alternatively, a mask may be deposited 407 after the active layer is fabricated 401 to cover the area of the active layer that will remain free of the blocking layer, followed by the application of the blocking layer 408. The mask may be removed 409 and the contact layer may be applied. The contact layer may be applied 406 to the blocking layer by any means known in the art for fabricating a contact layer on a photovoltaic active layer such as sputtering or electrodeposition.

In yet another embodiment of this invention, the blocking layer may be formed by a very high bandgap portion of the active layer. This semiconductor layer may be formed during the fabrication of the active layer. This layer may be grown and patterned to serve as a current blocking layer for cell protection. This high gap layer may be the last or one of the very last layers deposited during the epitaxial or diffusion process in order to allow proper patterning. Alternatively, wet oxidation of an Al-containing III-V compound semiconductor may be used to create the dielectric, as is known in the Vertical Cavity Surface Emitting Laser (VCSEL) art. These methods may be followed by etching or other processes for removing the high bandgap blocking layer from the portion of the active layer to be exposed to solar radiation. In still another embodiment of this invention, a high band gap layer may be disposed between the active layer and the top contact layer by applying a diffusive disordered of a superlattice containing alternate layers of high and low band gap semiconductor material. This may create a homogenous layer of conducting material surrounded by current blocking superlattice.

The invention may prevent the previously described current leakage mechanism in solar cells, especially ones operating at high currents. To the extent that the shadowed material allows leakage currents to develop, this invention may also increase cell efficiency by blocking those leakage currents. This is particularly valuable as the total area of the active layer decreases relative to exposed portion of the active layer 210. In one embodiment, the blocking layer may cover 30% or less of the surface of the active layer of the solar cell. In another embodiment of this invention, the blocking layer may cover 10% or less of the surface of the active layer of the solar cell. The area of the active layer may be small, such as in a 1 mm×1 mm square. A person skilled in the art will recognize that the essence of this invention is not limited to a particular semiconductor or even to semiconductor solar cells, but applies also to thin film, polycrystalline, amorphous and organic materials as well. The essential aspects of this invention apply equally to multi-junction and single junction cell constructs containing any number of p/n junctions, connecting tunnel junctions, and supporting structures. The active layer may also include anti-reflective coatings, passivation layers or any other additional layers associated with solar cells. The area and geometry of the blocking layer may be adjusted to optimize other aspects of cell performance such as contact resistance and peripheral current collection.

In FIGS. 1 and 2 the term “layer” applies to one or more distinct layers of material forming a current collecting structure and may include but is not limited to such constructs as the tunnel junction, back-surface fields, top window layers, contacting layers and so forth, as are known in the present or future art, as needed to construct an efficient solar cell.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention. Furthermore, those of ordinary skill in the art will appreciate that the foregoing description is by way of example only, and is not intended to limit the invention. Thus, it is intended that the present subject matter covers such modifications and variations.

What is claimed:

1. A solar cell comprising:
an active layer with an upper surface;
a top contact layer positioned over the upper surface of the active layer, wherein the top contact layer has a bottom surface and a side surface;
a blocking layer capable of impeding current flow, wherein at least a portion of the blocking layer is disposed between a portion of the upper surface of the active layer and the bottom surface of the top contact layer; and
a gridline electrically connecting the active layer to the side surface of the top contact layer.

2. The solar cell of claim 1, wherein the blocking layer is comprised of a dielectric material.

3. The solar cell of claim 2, wherein the dielectric material is selected from the group consisting of SiNₓ, polyamide, SiO₂, and Si_{y}Nₓ, and wherein x is a value between one and five and y is a value between one and five.

4. The solar cell of claim 1, wherein the blocking layer is a high bandgap semiconductor material.

5. The solar cell of claim 1, wherein the bottom surface of the top contact layer is completely covered by the blocking layer.

6. The solar cell of claim 1, wherein the active layer comprises multiple p/n junctions.

7. The solar cell of claim 1, wherein the blocking layer comprises two strips that cover less than 30 percent of the top surface of the active layer.

8. The solar cell of claim 1, wherein the blocking layer comprises two strips that cover less than 10 percent of the top surface of the active layer.

9. The solar cell of claim 1, further comprising an adhesion layer between the blocking layer and the active layer.

10. A method of making a solar cell comprising:
providing an active layer with a top surface;
applying a blocking layer with an upper surface to a portion of the top surface of the active layer, wherein the blocking layer is capable of impeding a current flow;
applying a contact layer to at least a portion of the upper surface of the blocking layer, wherein the contact layer has a bottom surface and a side surface; and
electrically connecting a gridline between the active layer and the side surface of the contact layer.

11. The method of claim 10, wherein the blocking layer comprises a dielectric material.

12. The method of claim 10, wherein the step of applying the blocking layer comprises masking to direct the location of the blocking layer.

13. The method of claim 10, wherein the blocking layer comprises a high bandgap semiconductor layer.

14. The method of claim 11, wherein the dielectric material is selected from the group consisting of SiNₓ, polyamide, SiO₂, and Si_{y}Nₓ, and wherein x is a value between one and five and y is a value between one and five.

15. The method of claim 10, wherein the blocking layer covers the bottom surface of the contact layer.

16. The method of claim 10, further comprising the step of applying an anti-reflective coating to the top surface of the active layer.

17. The method of claim 11, wherein the step of applying a blocking layer further comprises applying an adhesion layer between the upper surface of the blocking layer and the bottom surface of the contact layer.
